(19) United States
(12) Patent Application Publication
(10) Pub. No.: US 2017/0040317 A1
(43) Pub. Date: Feb. 9, 2017

(54) Semiconductor Device with a Laterally Varying Doping Profile, and Method for Manufacturing Thereof

(71) Applicant: Infineon Technologies Dresden GmbH, Dresden (DE)

(72) Inventors: Stefan Tegen, Dresden (DE); Martin Bartels, Dresden (DE); Marko Lemke, Dresden (DE); Ralf Rudolf, Dresden (DE); Rolf Weis, Dresden (DE)

(21) Appl. No.: 15/226,338

(22) Filed: Aug. 2, 2016

(30) Foreign Application Priority Data
Aug. 3, 2015 (DE) 102015112729.6

(51) Int. Cl. H01L 27/088; H01L 21/027; H01L 21/266; H01L 21/265; H01L 29/10; H01L 21/8234

(52) U.S. Cl. CPC H01L 27/0883; H01L 29/1095; H01L 21/823418; H01L 21/823412; H01L 21/266; H01L 21/2652; H01L 21/0274; H01L 21/823475; H01L 21/823431; H01L 27/0886

(57) ABSTRACT

A semiconductor device includes a semiconductor substrate having a first side. At least a first doping region is formed in the semiconductor substrate. The first doping region has a laterally varying doping dosage and/or a laterally varying implantation depth.

### TECHNICAL FIELD

Embodiments described herein relate to semiconductor devices having a laterally varying doping profile such as power FETs having a plurality of cascaded semiconductor elements each forming a single FET. Further embodiments described herein relate to methods for manufacturing semiconductor devices having a laterally varying doping profile.

### BACKGROUND

One aim in the development of semiconductor devices is the increase of the blocking capability, typically denoted by BV_{DSS}, and the reduction of the on-state resistance, typically denoted by R_{ON} or R_{DSON}. BV_{DSS} indicates the drain to source voltage at which a leakage current, typically denoted by I_{DSS}, exceeds a given value, when the semiconductor device is in blocking mode. The on-state resistance R_{ON} is the resistance of the semiconductor device when operated in forward conductive mode.

Both BV_{DSS} and R_{ON} depend on the doping concentration of the drift region. For example, the on-state resistance R_{ON} can be reduced by increasing the doping concentration. However, a high doping concentration in the drift region typically reduces the blocking capabilities of the semiconductor device.

There is therefore a desire to maintain or even improve device performance specifications.

### SUMMARY

According to an embodiment, a method for manufacturing a semiconductor device includes providing a semiconductor substrate having a first side; forming a first implantation mask having a varying thickness on the first side of the semiconductor substrate; defining regions for respective semiconductor elements in the semiconductor substrate; and implanting dopants into the semiconductor substrate through the first implantation mask to form at least a first doping region which is arranged at least partially below a first group of semiconductor elements and which has a laterally varying doping dosage and/or a laterally varying implantation depth.

According to an embodiment, a method for manufacturing a semiconductor device includes providing a semiconductor substrate having a first side; forming a source region in the semiconductor substrate at the first side of the semiconductor substrate; forming a drain region in the semiconductor substrate at the first side of the semiconductor substrate laterally spaced from the source region; forming an implantation mask having a varying thickness on the first side of the semiconductor substrate; and implanting dopants into the semiconductor substrate through the implantation mask to form a drift region which has a laterally varying doping dosage and/or a laterally varying depth between the source region and the drain region.

According to an embodiment, a semiconductor device includes a semiconductor substrate having a first side; a source metallization on the first side of the semiconductor substrate and in contact with source regions which are formed in the semiconductor substrate; a drain metallization on the first side of the semiconductor substrate and in contact with drain regions which are formed in the semiconductor substrate; and at least a first doping region formed in the semiconductor substrate, wherein the first doping region has a laterally varying doping dosage and/or a laterally varying implantation depth.

Those skilled in the art will recognize additional features and advantages upon reading the following detailed description, and upon viewing the accompanying drawings.

### BRIEF DESCRIPTION OF THE DRAWINGS

The components in the figures are not necessarily to scale, instead emphasis being placed upon illustrating the principles of the invention. Moreover, in the figures, like reference signs designate corresponding parts. In the drawings:

FIG. 1 illustrates a process for manufacturing a semiconductor device according to an embodiment;

FIGS. 2A and 2B illustrate further processes for manufacturing a semiconductor device according to an embodiment;

FIG. 3 illustrates a semiconductor device according to an embodiment;

FIGS. 4A to 4C illustrate different processes for manufacturing a semiconductor device according to an embodiment;

FIG. 5 illustrates a plane view on a semiconductor device according to an embodiment;

FIG. 6 illustrates a cross sectional view of a portion of the semiconductor device of FIG. 5;

FIG. 7 illustrates a 3-dimensional view of a portion of a semiconductor device according to an embodiment described herein;

FIG. 8 illustrates a 3-dimensional view of a portion of a semiconductor device according to an embodiment described herein;

FIGS. 9A to 9E illustrate processes for manufacturing a semiconductor device according to an embodiment;

FIGS. 10A to 10D illustrate processes for manufacturing a semiconductor device according to an embodiment; and

FIGS. 11A and 11B illustrate processes for manufacturing a semiconductor device according to an embodiment;

### DETAILED DESCRIPTION

In the following detailed description, reference is made to the accompanying drawings, which form a park hereof, and in which are shown by way of illustration specific embodiments in which the invention may be practiced. In this regard, directional terminology, such as “top”, “bottom”, “front”, “back”, leading”, “trailing”, “lateral”, “vertical” etc., is used with reference to the orientation of the figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. The embodiments being described use specific language, which should not be construed as limiting the scope of the appended claims.

In this specification, a second side or surface of a semiconductor substrate is considered to be formed by the lower surface or back side while a first side or first surface is considered to be formed by the top or main side or surface of the semiconductor substrate. The terms “above” and “below” as used in this specification, likewise “top” and “bottom,” therefore describe a relative location of a structural feature to another structural feature with consideration of this orientation. Furthermore, spatially relative terms such as “under”, “below”, “lower”, “over”, “upper” and the like, are used for ease of description to explain the positioning of one feature relative to a second feature. These terms are intended to encompass different orientations of the device in addition to different orientations than those depicted in the figures. Further, terms such as “first”, “second”, and the like, are also used to describe various features, regions, sections, etc. and are also not intended to be limiting. Like terms may refer to like features throughout the description.

The terms “electrical connection” and “electrically connected” describes an ohmic connection between two features.

Herein, a “normal projection” onto a plane or surface means a perpendicular projection onto the plane or surface. In other words, the view direction is perpendicular to the surface or plane.

The semiconductor substrate can be made of any semiconductor material suitable for manufacturing semiconductor components. Examples of such materials include, without being limited thereto, elementary semiconductor materials such as silicon (Si), group IV compound semiconductor materials such as silicon carbide (SiC) or silicon germanium (SiGe), binary, ternary or quaternary III-V semiconductor materials such as gallium arsenide (GaAs), gallium phosphide (GaP), indium phosphide (InP), gallium nitride (GaN), aluminium gallium nitride (AlGaN), indium gallium phosphide (InGaPa) or indium gallium arsenide phosphide (InGaAsP), and binary or ternary II-VI semiconductor materials such as cadmium telluride (CdTe) and mercury cadmium telluride (HgCdTe) to name few. The above mentioned semiconductor materials are also referred to as homojunction semiconductor materials. When combining two different semiconductor materials a heterojunction semiconductor material is formed. Examples of heterojunction semiconductor materials include, without being limited thereto, silicon (SiₓC₁₋ₓ) and SiGe heterojunction semiconductor material. For power semiconductor applications currently mainly Si, SiC and GaN materials are used.

N-doped regions are referred to as of first conductivity type while p-doped regions are referred to as of second conductivity type. It is, however, possible to exchange the first and second conductivity type so that the first conductivity type is p-doped and the second conductivity type is n-doped.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

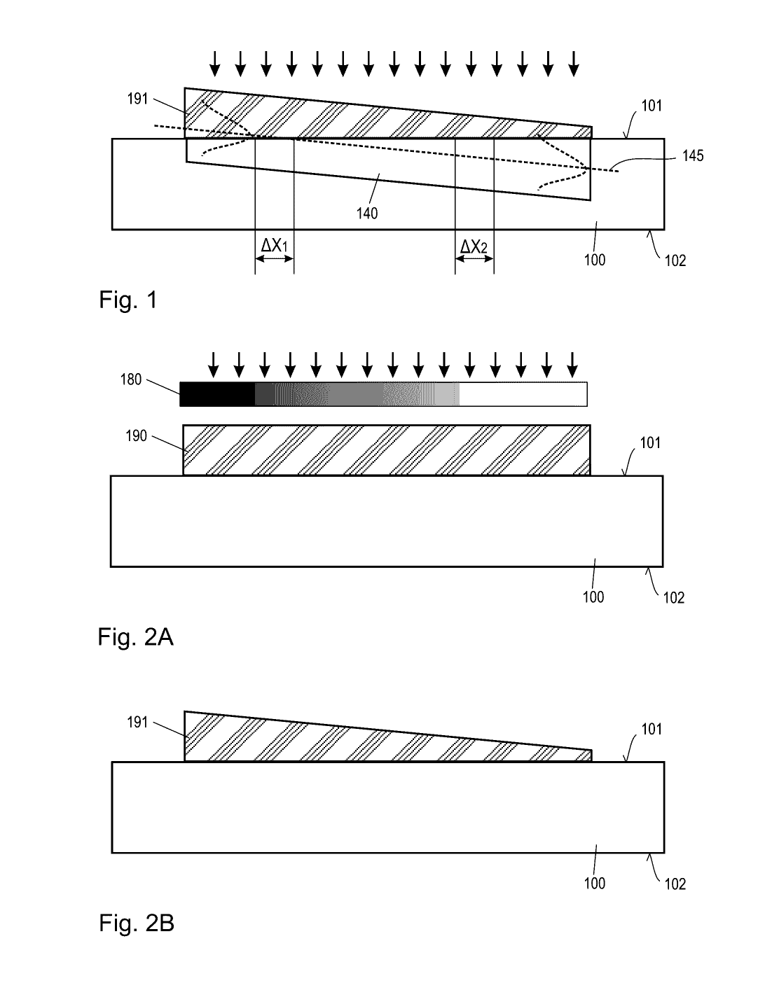

FIG. 1 illustrates a method for manufacturing a semiconductor device according to an embodiment. A semiconductor substrate 100 having a first side 101 and a second side 102 opposite to the first side 101 is provided. An implantation mask 191 having a laterally varying thickness is formed on the first side 101 of the semiconductor substrate 100, The implantation mask 191 is also referred to as first implantation mask in other embodiments. In a further process, dopants (illustrated by the downwardly pointing arrows) are implanted into the semiconductor substrate 100 through the implantation mask 191 to form at least a doping region 140 which has a laterally varying doping dosage and/or a laterally varying implantation depth. The doping region 140 is also referred to as first doping region in other embodiments.

The thickness of the implantation mask 191 is understood to be in vertical direction perpendicular to the first side 101 of the semiconductor substrate 100. A laterally varying thickness means that the (vertical) thickness is different at different lateral locations. The implantation mask 191 can therefore include regions of different thicknesses and can also include regions of constant thickness. For example, the implantation mask 191 can include at least a first region with a laterally varying thickness and at least a second region with a constant thickness. Furthermore, the implantation mask 191 can include at least two regions with different varying thicknesses, for example regions having a different slope or gradient.

As illustrated in FIG. 1, the implantation profile in vertical direction, i.e. in a direction perpendicular to the first side 101, has a given distribution with an implantation peak at a given depth. Since the implantation mask 191 has a thickness variation in lateral direction (laterally varying thickness), the vertical location of the implantation peak, and thus the implantation depth, also varies depending on the local thickness of the implantation mask 191. The vertical location of the implantation peak is indicated by line 145 which shows an increasing depth of the implantation peak relative to the first side 101 with reducing thickness of the implantation mask 191.

The depth variation of the implantation peak is shown in FIG. 1 to vary with the thickness of the implantation mask 191. Depending on the absorption behavior of the implantation mask 191 and of the semiconductor substrate 100, the implantation depth in the semiconductor substrate 100, when defined as location of the implantation peak, can be approximately constant for semiconductor substrates 100 which decelerate the implanted dopants more strongly than the implantation mask 191. The depth variation within the semiconductor substrate 100 is in this case less pronounced. However, the amount of the implanted dopants per unit area, i.e. the doping dosage, laterally varies as the doping dosage depends on the thickness of the implantation mask 191. Hence, even when the implantation depth does not vary significantly, the doping dosage can vary significantly based on the thickness variation of the implantation mask 191.

For illustrating purposes, the doping dosage in the region denoted by ΔX₁ is less than the doping dosage in the region denoted by ΔX₂, ΔX₁ and ΔX₂ indicate areas of the same size. The doping dosage is thus the number of implanted dopants per unit area in the main surface of the semiconductor substrate 100, which main surface is formed in this embodiment by the first side 101. An increasing dopant dosage also means that the total number of the implanted dopant increases in the volume of a vertical column, which is defined by the unit area and extending from the first side vertically through the semiconductor substrate 100. Such an increase, or generally the variation of the total number of implanted dopants, can be beneficially used to shape the geometrical field in the doping region 140.

As illustrated in FIG. 1, the doping dosage, and thus the total number of implanted dopants per vertical column, increases with reducing thickness of the implantation mask 191. Forming a doping region 140 with a laterally varying doping dosage is, for example beneficial for doping regions which act as a drift zone or drift region of a semiconductor device.

FIGS. 2A and 2B illustrate processes for manufacturing an implantation mask 191 having a laterally varying thickness. For example, the implantation mask 191 can be formed by grayscale lithography as exemplified by FIGS. 2A and 2B, A photosensitive layer 190 is formed on the first side 101 of the semiconductor substrate 100. The photosensitive layer 190 can be, for example, a photoresist with a low-contrast behavior different to a standard resist which has a binary contrast behavior. The developing rate of a low-contrast photoresist varies with the exposure rate while a binary photoresist can be developed only in regions receiving an exposure rate above a given threshold (for positive photoresists). Therefore, a low-contrast photoresist is capable of transferring a laterally varying exposure rate into a lateral thickness variation.

The photosensitive layer 190 is exposed to radiation through a grayscale mask layer 180 which has a laterally varying transmittance. The radiation can be light, such as UV light, or electron beam radiation depending on the photoresist used for the photosensitive layer 190.

In a further process, the photosensitive layer 190 is developed to form the implantation mask 191 having the laterally varying thickness. In FIGS. 2A and 2B, a positive resist is used for the photosensitive layer 190 so that regions which are more exposed to radiation will be more developed, and thus removed, than regions which are less exposed. If a negative photoresist is used, the relation between the exposure rate and the development is reversed.

According to an embodiment, an implantation mask 191 with a laterally varying thickness also includes implantation masks which has a thickness modulation so that a mean thickness of the implantation mask laterally varies. For example, a thickness modulation can be obtained by forming a plurality of small trenches in the photosensitive layer 190. The trenches can have a constant width and are arranged at varying distance to each other to obtain the mean thickness variation and/or the trenches can have a varying width. In any case, a mean thickness of the implantation mask can be defined which mean thickness depends on the number and/or size of the trenches per unit area Typically, the trenches are thinner than the initial thickness of the photosensitive layer 190 to provide for a variation at small steps.

Using grayscale lithography is beneficial as only a single mask 180 is needed in comparison to approaches which use separate implantation masks to form doping regions with step-wise increasing or decreasing doping dosage. A single grayscale mask, and a photoresist material that is capable of transferring a graded exposure into a graded thickness, allows the formation of any laterally varying thickness profile so that the doping dosage and/or the implantation depth can be adjusted according to circumstances. Since only a single lithographic process is used, mask misalignments can be prevented and the manufacturing costs reduced. Since only a single implantation process is needed, the whole implantation is carried out at a given implantation dose unlike separate implantation steps which may have a varying implantation doses. Furthermore, a single implantation process requires less time.

The obtained doping dosage and/or implantation depth can be verified, for example, by a SSRM measurement (scanning spread resistance microscopy).

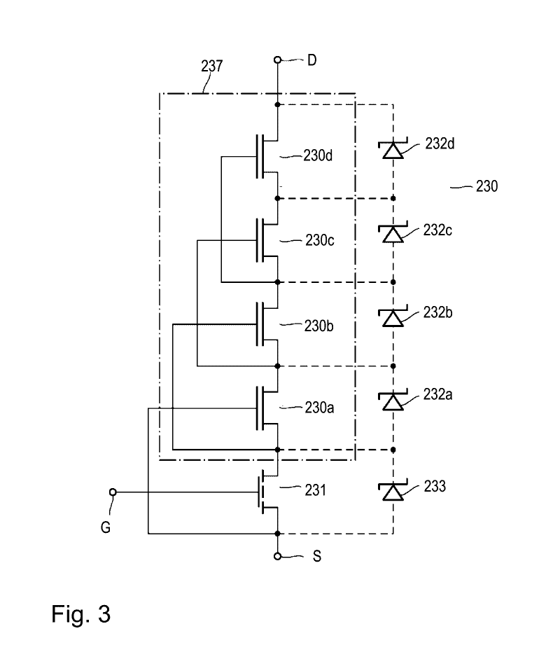

FIG. 3 illustrates a lateral power FET for which a doping region with laterally varying dopant dosages is beneficial.

FIG. 3 shows an equivalent circuit diagram of a semiconductor device 230 according to an embodiment. The semiconductor device 230 comprises an enhancement transistor 231 (normally-off transistor) and a plurality of depletion transistors 230a to 230d (normally-on transistors). The enhancement transistor 231 comprises a gate electrode, a drain region and a source region. The gate electrode G of the enhancement transistor 231 is also the control gate for the semiconductor device 230.

When a suitable voltage is applied to the gate electrode G, the enhancement transistor 231 is rendered conductive. The plurality of the depletion transistors 230a to 230d are connected in series with each other and to the enhancement transistor 231. The entirety of the depletion transistors 230a to 230d can be considered to act as a drift zone 237 of the enhancement transistor 231. In this case, the terminal D can be regarded as a drain terminal of the power semiconductor device 230. The terminal S, which is connected with the source of the enhancement transistor 231, acts as source of the semiconductor device 230.

As shown in FIG. 3, the voltage appearing at the drain of the depletion transistor 231 is applied to the gate of the depletion transistor 230b. The voltage appearing at the source of the depletion transistor 231 is applied to the gate of the transistor 230a. Each of the depletion transistors 230c to 230d has its gate electrode connected to the drain of another depletion transistor 230a to 230b which is arranged two positions in the series before the respective depletion transistors 230c to 230d. Therefore, the output of any transistor 231, 230a to 230d in the series determines the gate voltage which is applied to a transistor at a later position within the series. The semiconductor device 230 thus formed is a so-called ADZFET (“active drift zone field effect transistor”) having a controllable drift zone formed by the depletion transistors 230a to 230d.

The semiconductor device of FIG. 3 illustrates depletion transistors 200a to 230d and one enhancement transistor 231. While the semiconductor device typically includes one enhancement transistor 231, the number of the depletion transistors 230a to 230d is not limited and can be adapted in view of the desired blocking voltage.

The semiconductor device 230 can additionally comprise a plurality of clamping elements 233, 232a to 232d, wherein each of the clamping elements is connected in parallel to each of the transistors 231 and 230a to 230d. An overvoltage protection for the respective transistor 231 and 230a to 230d is provided by the clamping elements 233, 232a to 232d. The clamping element can be Zener diodes or other suitable elements such as PIN diodes, tunnel diodes, avalanche diodes or the like. The clamping elements 233, 232a to 232d are optional.

Each of the transistors 231, 230a to 230d is capable of blocking a given voltage such as, for example, 20 V. Due to the series connection, the total blocking voltage of the semiconductor device 230 is much larger and approximately equal to the blocking voltage of each transistor 231, 230a to 230d multiplied by the number of the transistors 231, 230a to 230d. It is thus possible to form a power semiconductor device 230 capable of blocking large voltages by a series of transistors each being capable of blocking a much lower voltage. Since the blocking voltage which each of the transistors 231, 230a to 230d has to withstand is moderate, the device requirements are not so demanding than for a single transistor which would need to block a high voltage.

The transistors 231, 230a to 230d are also referred to as semiconductor elements in other embodiments.

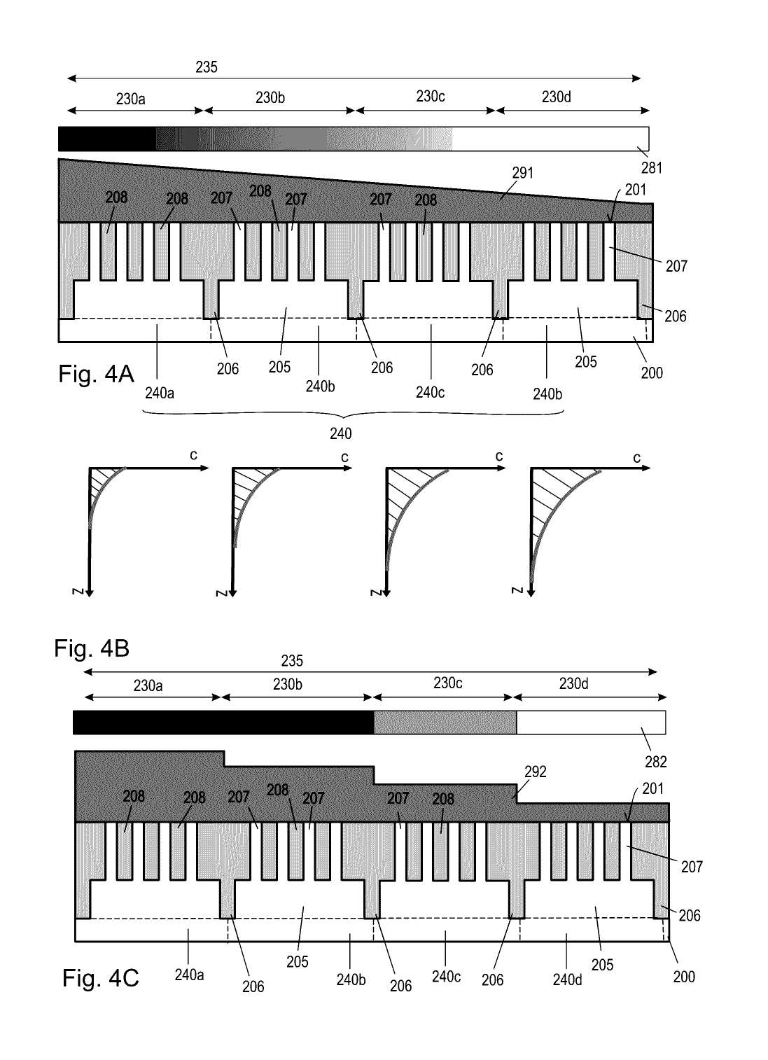

FIGS. 4A to 4C illustrate embodiments of semiconductor devices formed as ADZFETs as described above. Each of the transistors 231, 230a to 230d, which are referred to as semiconductor elements hereinafter, is integrated in a common semiconductor substrate 200. The semiconductor substrate 200 includes a plurality of first mesa regions 205 which are laterally separated from each other by first trenches 206. Each of the first mesa regions 205 defines the region where a single semiconductor element 230a to 230d is formed. The first mesa regions 205 can therefore also referred to as element mesas or device mesas.

FIGS. 4A and 4C illustrate only the depletion transistors 230a to 230d for ease of explanation. However, the enhancement transistor 231 is also formed in a respective first mesa region 205. The depletion transistors 230a to 230d form together a first group 235 of semiconductor elements.

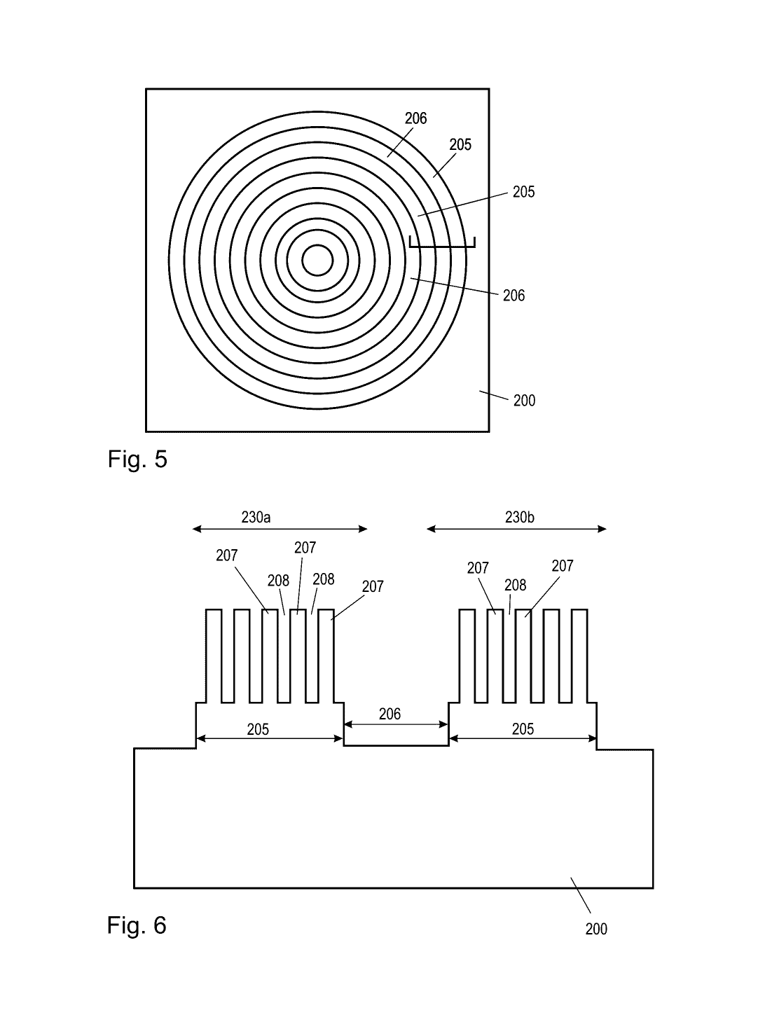

Each first mesa region 205 includes a plurality of second mesa regions 207 which are separated from each other by second trenches 208. The second mesa regions 207 are much smaller than the first mesa regions 205 and can be described as thin fin-shaped regions. As is apparent from FIG. 5, which shows a plane view onto a semiconductor device 230, the first mesa regions 205 can be concentrically arranged so that each of the first mesa regions 205 forms a closed ring-structure. The second mesa regions 207 are therefore also concentrically arranged as illustrated in FIG. 6 which shows an enlarged view of a vertical cross-section of the semiconductor device 230. Each ring-like first mesa region 205 forms a respective one of the enhancement devices 231 and the depletion devices 230a to 230d (semiconductor elements). The enhancement device 231 can be formed centrally with the depletion devices 230a to 230d formed concentrically around the enhancement devices 231. Alternatively, one of the depletion devices 230a to 230d can be formed centrally with the remaining depletion devices 230a to 230d formed concentrically around the central depletion device 231, and the enhancement device 231 being formed as the outer peripheral device.

A doping region 240 is arranged below the first mesa regions 205, which doping region 240 can be considered to act as a drift zone of the semiconductor device 230 for a lateral reduction of the blocking voltage. The doping region 240 includes a plurality of sub-region 240a to 240d, each formed below a respective one of the first mesa regions 205. The doping region 240 laterally extends across the first group 235 of semiconductor elements 230a to 230d when seen in a plane projection onto the first side of the semiconductor substrate 200.

The doping region 240 can have a ring-like shape, when seen in plane projection onto the first side 201, or can have a circular shape. Other shapes are also possible.

FIG. 4B illustrates the vertical doping profile, i.e. the curse of the doping concentration in vertical direction, in each of the sub-region 240a to 240d . The doping dosage of each of the sub-region 204a to 240d is the integral (hatched area) below the respective curve illustrated in FIG. 4B, The doping dosage is thus obtainable by integrating the doping concentration in vertical direction, i.e. along the z-axis.

As illustrated in FIGS. 4A and 4C, a first sub-region 240a of the first doping region 240 is formed to be arranged at least partially below a first semiconductor element 230a, and a second sub-region 240b of the first doping region 240 having a mean dopant dosage different to the mean doping dosage of the first sub-region 240a is formed to be arranged at least partially below a second semiconductor element 230b. Furthermore, a third sub-region 240c of the first doping region 240 is formed to be arranged at least partially below a third semiconductor element 230c, and a fourth sub-region 240d of the first doping region 240 is formed to be arranged at least partially below a fourth semiconductor element 230d. Each of the sub-regions 240a to 240d can have a doping dosage (or a mean doping dosage) and/or an implantation depth different to any of the sub-regions adjacent to this sub-region.

According to an embodiment, a respective sub-region 240a to 240d is assigned to a respective semiconductor element 230a to 230d. As is described in more detail below, each of the semiconductor elements 230a to 230d assumes a given electrical potential during blocking mode of the semiconductor device. The sub-regions 240a to 240d assist in the lateral relief of the blocking voltage.

For example, FIG. 4A illustrates an embodiment with a laterally continuously varying doping dosage and/or continuously varying implantation depth that is obtained by using an implantation mask 291 with a laterally continuously varying thickness. The embodiment illustrated in FIG. 4A shows a continuously decreasing thickness from left to right. For manufacturing the implantation mask 291, a mask layer 281 with a continuously varying transmission can be used as explained in connection with FIGS. 2A and 2B.

The doping dosage of the doping region 240 laterally increases from sub-region to sub-region in FIG. 4A. For each of the sub-regions 240a to 240d, a mean doping dosage can be defined even when the doping dosage continuously increases through the sub-regions. Each sub-region 240a to 240d therefore has a mean doping dosage different to an adjacent sub-region. The doping dosage of the doping region 240 can, for example, laterally vary by a factor of about at least 2, more particularly of about at least 3. For example, the doping dosage of the doping region 240 can vary in vertical and/or in lateral direction from 0% to 100%. Alternatively, the doping dosage of the doping region 240 can vary in vertical and/or in lateral direction from a minimum value to a maximum value. The minimum value and maximum value can be different for the lateral and vertical direction. The doping dosage can also vary stepwise. The lateral variation of the doping dosage can include a first sub-region having a minimum doping dosage and a second sub-region having a maximum doping dosage, wherein the maximum doping dosage is larger than the minimum doping dosage by a factor of about at least 2, more particularly by a factor of about at least 3, and even more particularly by a factor of about at least 4. When the doping dosage varies continuously, the maximum and minimum doping dosages are local dosages, for example measured at a lateral first end and at a lateral second end opposite the first end of the doping region 240. It is furthermore possible that the doping dosage increases from a first minimum at a lateral first end of the doping region 240 to a maximum in a laterally central region of the doping region 240 and then decreases from the maximum to a second minimum at a lateral second end of the doping region 240 that is opposite the first end. The first and second minimum can be equal or can be different.

According to an embodiment, the doping region 240 laterally extends over two, three or more semiconductor elements 230a to 230d and has a doping dosage and/or an implantation depth which laterally increases. Typically, the lateral increase along the lateral extension of the doping region 240 is by a factor of at least two for the doping dosage and by a factor of at least two for the implantation depth.

FIG. 40 illustrates another embodiment which employs an implantation mask 292 with a step-wise varying thickness. For manufacturing the implantation mask 292, a mask layer 282 with a step-wise varying transmission can be used. In this embodiment, each of the sub-regions 240a to 240d has a given constant doping dosage and the doping dosage thus varies step-wise in contrast to the doping dosage of the sub-regions 240a to 240d in the embodiment shown in FIG. 4A which varies continuously.

As explained in connection with FIG. 3, each of the depletion transistors 230a to 230d (semiconductor elements) carries a fraction of the total blocking voltage of the semiconductor device 230. In blocking-mode, each of the semiconductor elements 230a to 230d is at a different electrical potential and the blocking voltage laterally drops through the semiconductor elements 230a to 230d. More specifically, the blocking voltage drops form the source terminal S through the series formed by the enhancement transistor 231 and the depletion transistors 230a to 230d to the drain terminal T. The blocking voltage also laterally drops through the semiconductor region 240 as each of the semiconductor elements 230a to 230d is clamped at a given electrical potential during blocking mode. When providing the sub-regions 240a to 240d with different doping dosage, the course of the voltage drop can be shaped to increase the total blocking capabilities of the semiconductor device and the avoid that the electrical field locally exceeds a given threshold.

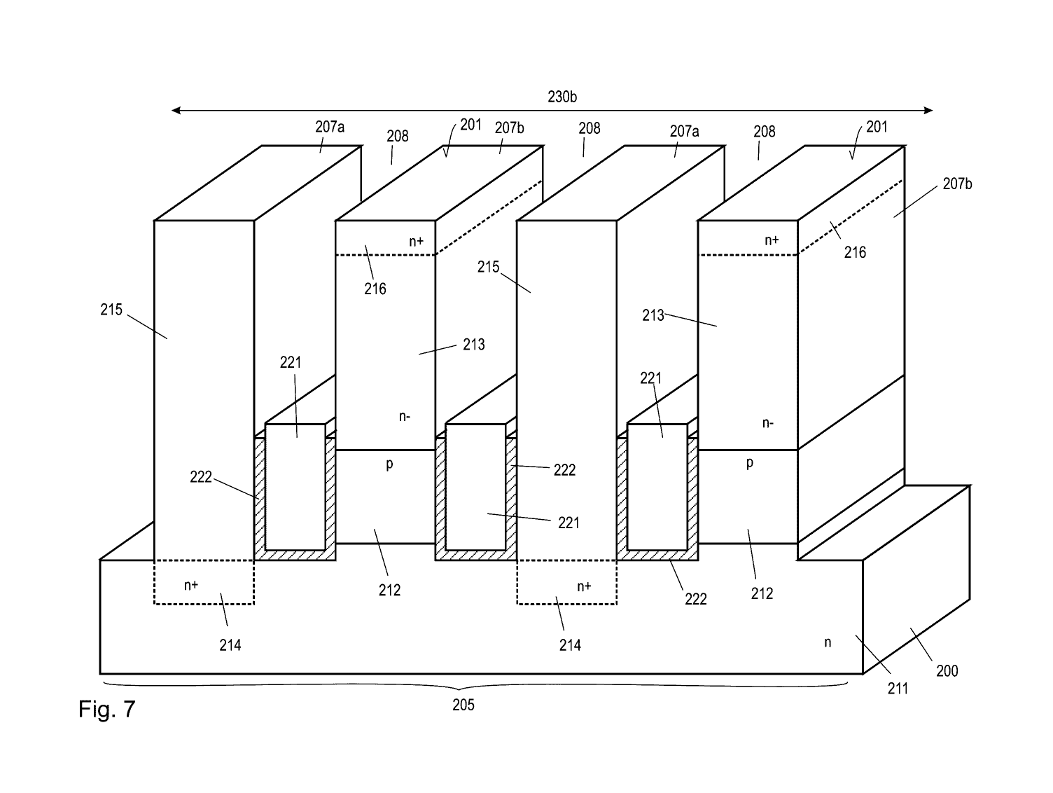

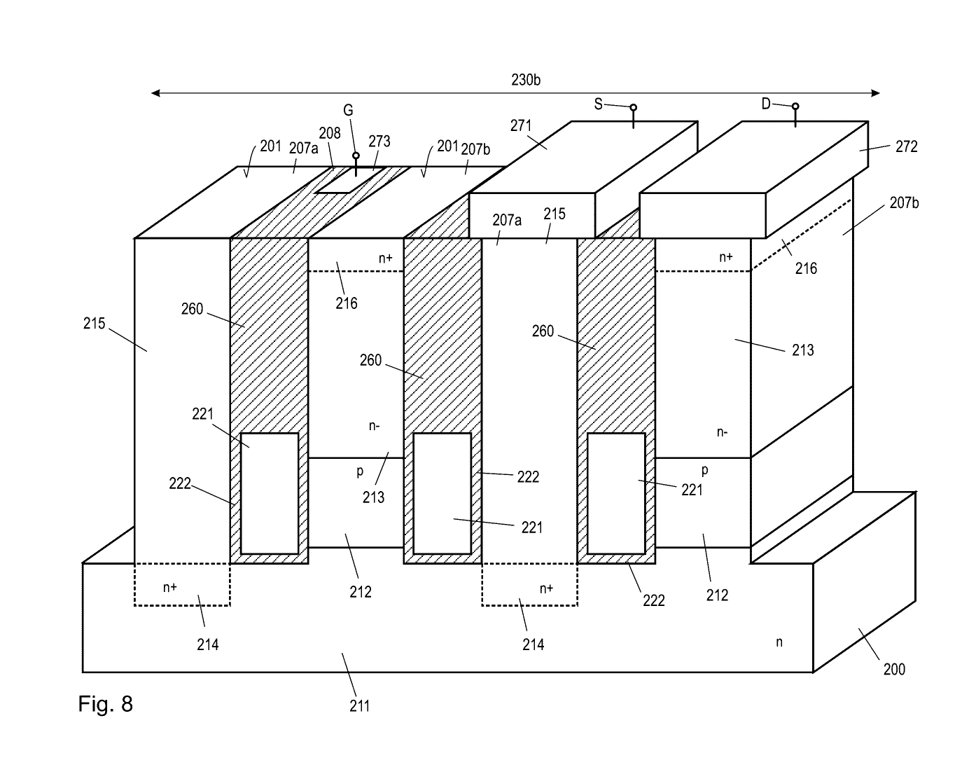

With reference to FIGS. 7 and 8, the structure of a semiconductor element 230a to 230d is explained in more detail. FIGS. 7 and 8 refer to the second semiconductor element 230b for illustration purposes only.

FIGS. 7 and 8 illustrate a portion of a first mesa region 205 of a single semiconductor element 230b. The first trenches 206 are not illustrated.

The first side 201 of the semiconductor substrate 200 is shown to be formed by the upper side of the second mesa regions 207a and 207b. Each of the second mesa regions 207a and 207b forms a respective fin of the semiconductor element 230b. Adjacent second mesa regions 207a and 207b are separated from each other by a respective one of the second trenches 208 and differ in their function and structure. Typically, the second mesa regions 207a and 207b forms an alternating arrangement of mesa regions 207a (first type of second mesa regions) forming source contacts 215 and mesa regions 207b (second type of second mesa regions) in which the body regions 212, drift regions 213 and drain regions 216 are formed. Two adjacent second mesa regions 207a and 207b form together a single cell of the semiconductor element 230b. Hence, each of the semiconductor elements 230a to 203d can include a plurality of transistor cells each having two second mesa regions.

The semiconductor elements can also be formed by other types of the FETs such as IGBTs. In this case, the drain region is replaced by an emitter region of opposite conductivity type.

The second mesa regions 207a (first type of second mesa regions), which form the source contacts 215, can be comprised of highly doped semiconductor material or of metal or metal alloy. The second mesa regions 207a extend from the first side 201 to respective source contact regions 214 integrated into the first mesa region 205, which source contact regions 214 are highly n-doped regions in this embodiment. The first mesa region 205 is n-doped in this embodiment and forms the source region 211.

The second mesa regions 207b (second type of second mesa regions) are comprised of semiconductor material, typically the same semiconductor material as for the first mesa region 205. The second mesa regions 207b can be formed by epitaxial deposition followed by etching. As illustrated in FIGS. 7 and 8, p-doped body regions 212, weakly n-doped drift regions 213, and highly n-doped drain regions 216 are formed in this order from the first mesa region 205, which forms respective source region 211, to the first side 201. The doping relations can also be reversed and are not limited to the specific embodiments illustrated herein.

Gate electrodes 221 are formed between any two adjacent second mesa regions 207a and 207b. More specifically, a gate electrode 221 is formed between a source contact 215, formed by the second mesa region 207a (first type of second mesa regions), and a semiconductor fin 207b, formed by the second mesa region 207b (second type of second mesa regions) and arranged adjacent to the source contact 215. The gate electrodes 221 are insulated from the source region 211 and the second mesa regions 207a, 207b by a gate dielectric 222.

When a voltage above a given threshold voltage is applied to the gate electrodes 221, an enhancement channel is formed in the body region 212 along the gate dielectric between the source region 211 and the drift region 213 in case of an enhancement device. In case of a depletion device, the intrinsically formed channel is depleted when the gate voltage exceeds a given threshold voltage and thus the ohmic connection between the source region 211 and the drift region 213 is interrupted.

The doping region having a laterally varying doping dosage and/or a laterally varying implantation depth is formed in the semiconductor substrate 200 below the first mesa region 205 and therefore not illustrated in FIGS. 7 and 8.

As illustrated in FIG. 8, a source metallization 271 is formed on the first side 201 of the semiconductor substrate 200 and in contact with the source contacts 215 and thus with the source regions 211. Furthermore, a drain metallization 272 is formed on the first side 201 of the semiconductor substrate 200 and in contact with drain regions 216. FIG. 8 also illustrates a gate metallization 273 which is in ohmic connection with the gate electrodes 221. The second trenches 208 between adjacent second mesa regions 207a and 207b are filled with an insulating material 260 above the gate electrodes 221.

Since each of the transistor cells only needs to block a comparably low voltage, such as 20 V, the blocking capabilities are not demanding. This improves the reliability of the semiconductor device 230.

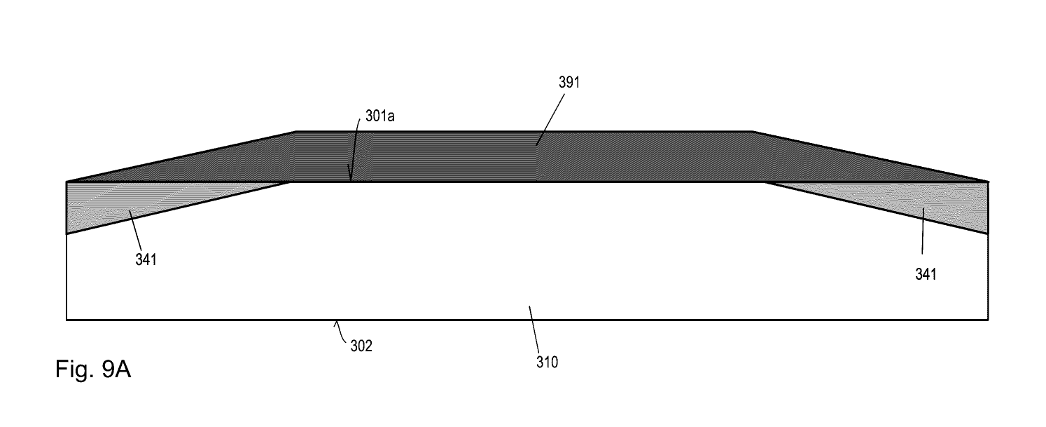

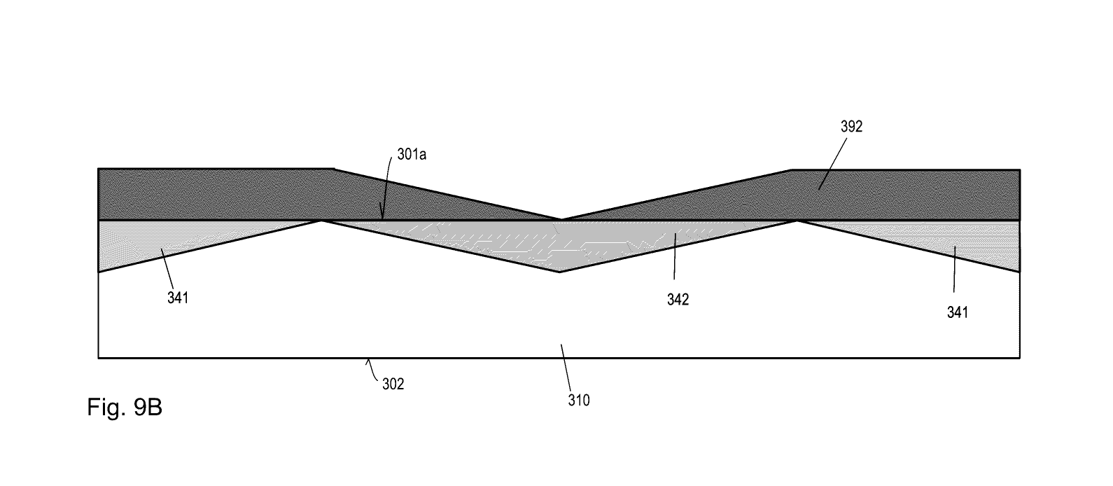

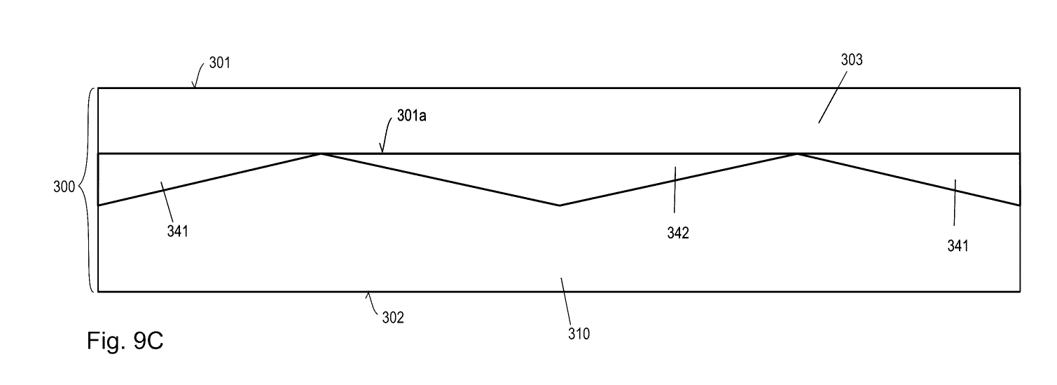

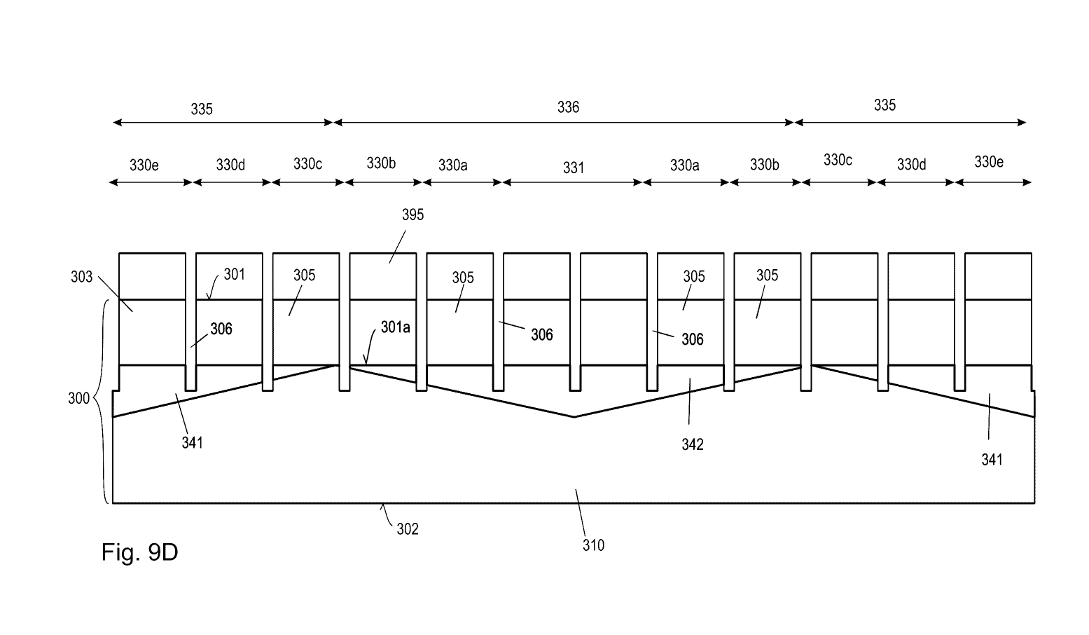

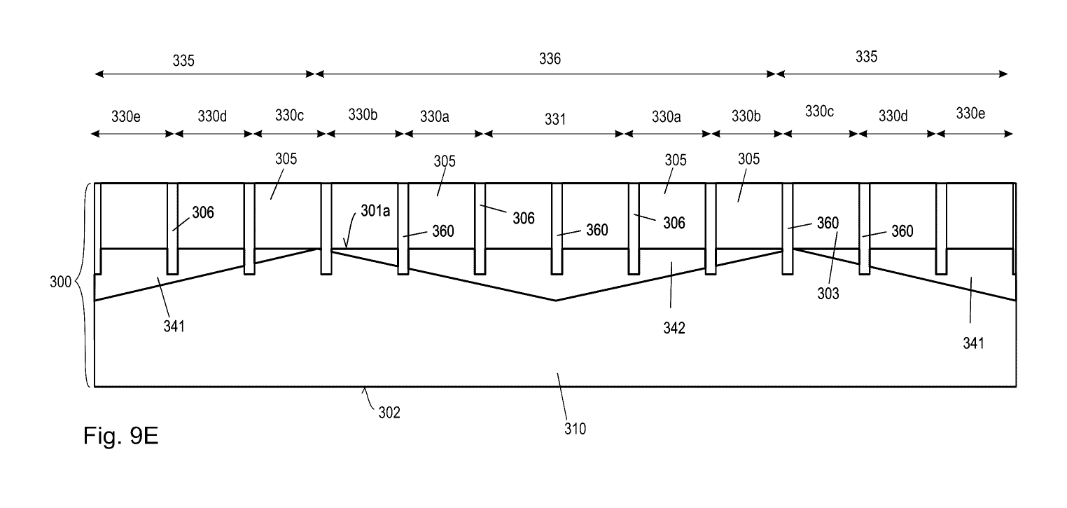

With reference to FIGS. 9A to 9E, processes for manufacturing a semiconductor device having a laterally varying doping dosage and/or a laterally varying implantation depth are illustrated.

A semiconductor body 310 having a first side 301 and a second side 302 opposite the first side 301 is provided. The semiconductor material can be any of the above mentioned materials. Typically, the semiconductor body 310 is silicon wafer, a silicon carbide wafer or a gallium nitride wafer, or a composite wafer. The wafer can be supported by a non-illustrated carrier wafer which can be temporally or permanently attached to the second side 302. The semiconductor substrate can be, for example, lightly n-doped.

A first implantation mask 391 having a laterally varying vertical thickness is formed on the first side 301 of the semiconductor body 310. The first implantation mask 391 can be formed according to the processes as explained in connection with FIGS. 2A and 2B. Other processes for forming the first implantation mask 391 are also possible.

The first implantation mask 391 has a relatively constant thickness over a central part of the semiconductor body 310 and a continuously reducing thickness towards the lateral or outer regions of the semiconductor body 310.

In a further process, as illustrated in FIG. 9A, first dopants are implanted into the semiconductor body 310 through the first implantation mask 391 to form at least a first doping region 341. The first doping region 341 is formed in this embodiment in the peripheral or laterally outer region of the semiconductor body 310. Implantation of the first dopants into the central part of the semiconductor body 310 is prevented by the first implantation mask 391. The implanted first dopants can be, for example, P, As or Sb to form an n-doped first doping region 341 to form an n-doped region.

The implantation can occur only in deep regions of the semiconductor body 310 and/or in shallow regions. It is, for example, possible to form the first doping region 341 as a shallow region followed by an epitaxial deposition to bury the first doping region 341.

As illustrated in FIG. 9B, the first implantation mask 391 is removed and a second implantation mask 392 is formed on the first side 301 of the semiconductor body 310. The second implantation mask 392 has a large thickness in the lateral or outer regions of the semiconductor body 310 where the first doping region 341 has been formed to avoid that dopants are implanted into the first doping region 341 during a subsequent implantation process. The thickness of the second implantation mask 392 reduces towards the central part of the semiconductor body 310. Second dopants, which are implanted into the semiconductor body 310 during a second implantation process, are thus only implanted into the central part of the semiconductor body 310. The resulting second doping regions 342 has an increasing doping dosage and/or implantation depth toward the laterally central part of the of the semiconductor body 310. The second dopants can be B, BF₂, or Al to form a p-doped region.

The second implantation mask 392 can be formed by grayscale lithography as described above in connection with FIGS. 2A and 2B. The second doping region 342 has also a laterally varying doping dosage and/or implantation depth as illustrated in FIG. 9B.

When seen in a plan projection onto the first side 301, the second doping region 342 is surrounded by the first doping region 341 which has a laterally increasing doping dosage towards the lateral edge or rim of the semiconductor body 310. The doping dosage of the second doping region 342 is highest in its central portion and decreases from the central region towards the laterally outer edge of the second doping region 342. The doping dosage of the first doping region 341 decreases from the outside to the inside in lateral direction. The first doping region 341 can have a ring-liked shape to surround the second doping region 342 which can have a circular shape, when seen in plane projection onto the first side 301.

Typically, the first and second doping regions are of different conductivity type. Therefore, dopants of different conductivity type are used for forming the first and second doping region 341, 342. In the embodiments illustrated in FIGS. 9A to 9E, the first doping region 341 is n-doped and the second doping region 342 is p-doped.

The order of the formation of the first doping region 341 and second doping region 342 can also be reversed.

In a further process, as illustrated in FIG. 90, the second implantation mask 392 is removed and an epitaxial layer 303 is formed on the first side of the semiconductor body 310 to bury the first and second doping regions 341, 342. The semiconductor body 310 together with the epitaxial layer 303 form a semiconductor substrate 300 which is used a substrate for integrating the semiconductor device.

FIG. 9D illustrates further processes which includes formation of an etching mask 395 on the upper side of the epitaxial layer 303 for defining the location and size of the first trenches 306 and first mesa regions 305. Using the etching mask 395, the epitaxial layer 303 and partially the semiconductor body 310 is etched to form a plurality of first trenches 306 which delimit adjacent first mesa regions 305. The etching thus defines forms the regions for a respective semiconductor element.

For example, the enhancement device 331 can be formed in a laterally central part of the semiconductor body 310 which is ring-like surrounded by the depletion devices 330a to 330e. The ring-like arrangement is exemplified in FIG. 5. The laterally outer depletion devices 330c to 330e form together, for example, a first group 335 of semiconductor elements, and the enhancement device 331 together with adjacent depletion devices 330a to 330b form a second group 336 of semiconductor elements. Since the enhancement device 331 is formed in this embodiment in the central part, the source terminal is laterally central and the drain terminal is laterally outer to the source terminal. The first doping region 341, which is arranged laterally outer to the second doping region 342, is in this embodiment n-doped and the second doping region 342 is p-doped. The illustrated doping relations relate to so-called N-FET devices.

Alternatively, a first depletion device 330e can be formed laterally central, surrounded by the remaining depletion device 330d to 330a and the enhancement device 331 as the most outer device. In this case, the source terminal laterally surrounds the drain terminal which is central. The first doping region 341 is then p-doped and the second doping region is p-doped.

The concentric arrangement of the devices 311, 330a to 330e can be as shown in FIG. 5.

When using N-FET devices, the doping region of the first and second doping regions 341, 341 that is formed below the drain terminal is n-doped (first conductivity type) and the respective other doping region formed below the source terminal is p-doped (second conductivity type). N-FETs include an n-doped substrate 200 or source 211 as shown in FIG. 8. With reference to FIGS. 9C to 9E, the source region is formed by the region 303 which can be an epitaxial layer formed on the semiconductor body or wafer 310, or an integral layer of the semiconductor body or wafer 310 and formed by implantation.

When using P-FETs for forming the semiconductor elements, the doping relations are inversed.

The first doping region 341 is arranged to be at least partially below the first group 335 of semiconductor elements 330c to 330e. The second doping region 342 is arranged to be at least partially below the second group 336 of semiconductor elements 331, 330a to 330b.

In a further process, the first trenches 306 are filled with an insulating material 360 to improve lateral insulation.

In further processes, as exemplified in FIGS. 6, 7 and 8, a plurality of fin regions 207, which were referred to above as second mesa regions 207, are formed on or in each of the first mesa regions 305. The fin regions 207 extend from an upper side of the first mesa regions 305 to the first side 301. Adjacent fin regions 207 are spaced from each other by second trenches 208 which extends to the upper side of the first mesa regions 305.

Subsequently, gate electrodes 221 are formed between adjacent fin regions 207 followed by the formation of a first metallization 271 in electrical contact with a first group of fin regions 207a (first type of second mesa regions), and a second metallization 272 in electrical contact with a second group of fin regions 207b (second type of mesa regions). The first group of fin regions 207a forms the source contacts 215 while the second group of fin regions 207b includes the body regions 212, the drift regions 213, and the drain regions 216.

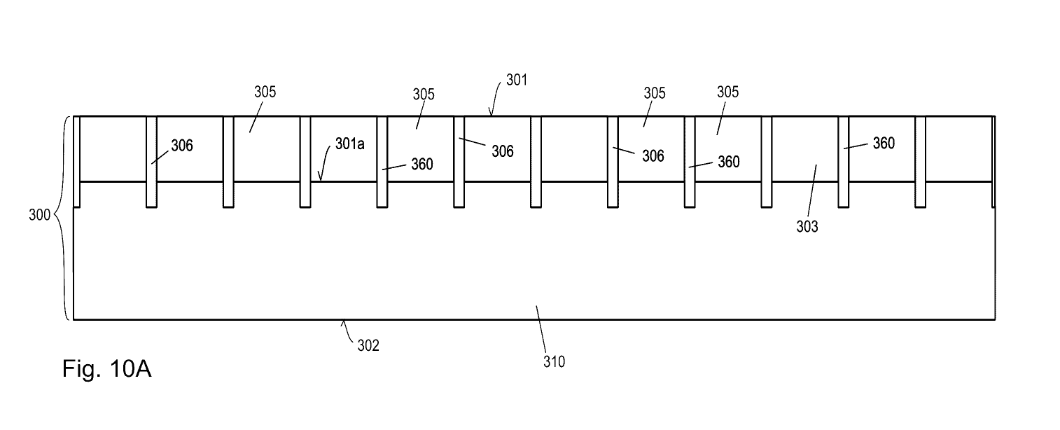

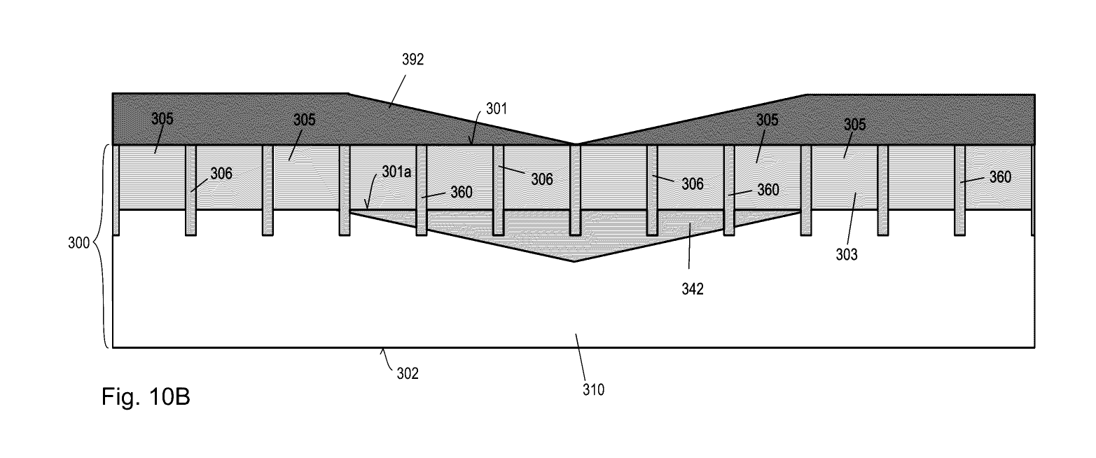

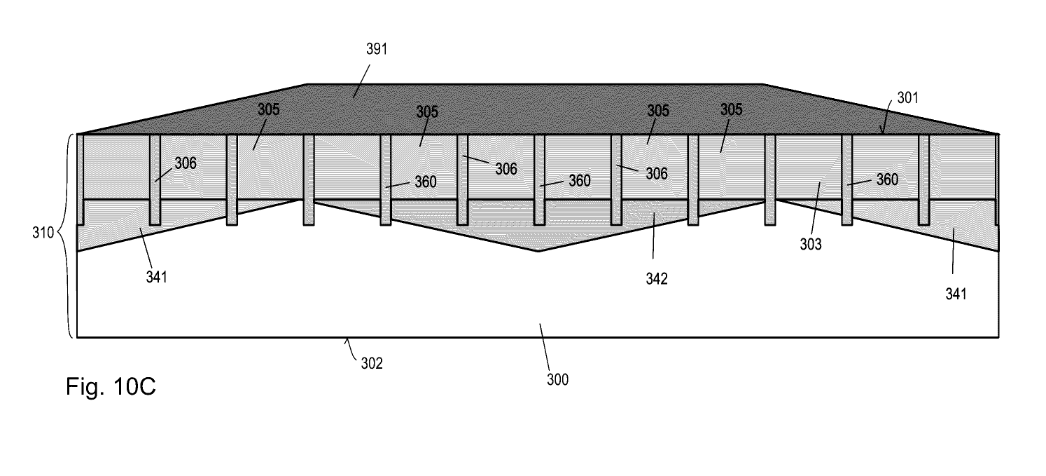

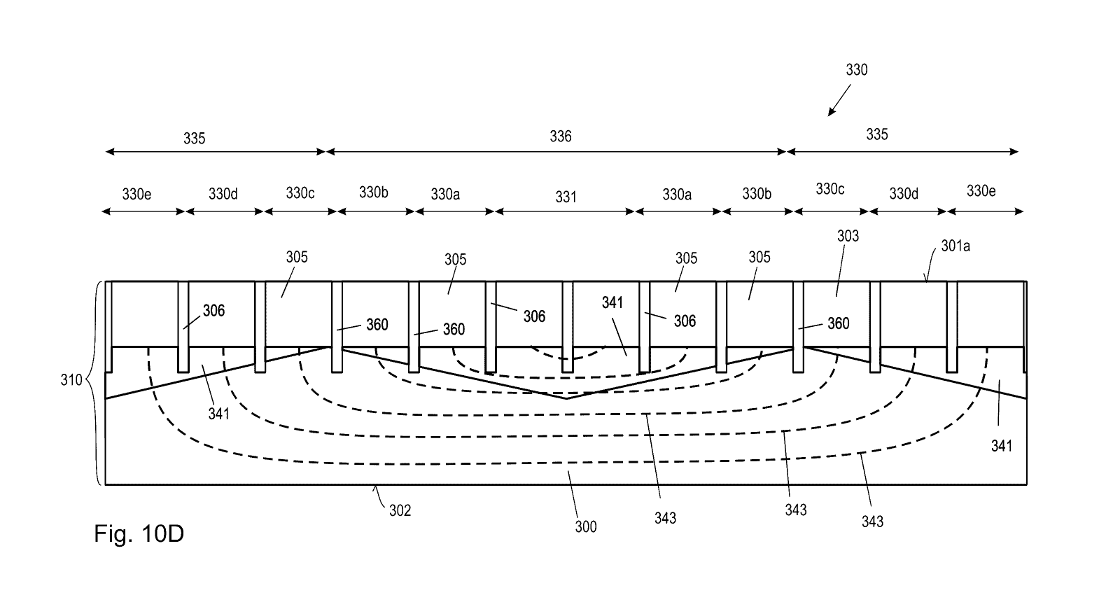

With reference to FIGS. 10A to 10D, a variation of the manufacturing processes is described. Basically, the order of the process is changed. As illustrated in FIG. 10A, the epitaxial layer 303 is formed first followed by the etching of the semiconductor substrate 300 which includes the semiconductor body 310 and the epitaxial layer 303. Alternatively, layer 303 is an integral part of the semiconductor body 310, i.e. of the semiconductor wafer, and formed by implantation.

In a further process, the second doping region 342 is formed bevor the formation of the first doping region 341 as illustrated in FIGS. 10B and 10C.

FIG. 10D illustrates the final structure with the course of the equipotential lines 343 in the semiconductor substrate 300. Due to the graded doping dosage of the first and second doping regions 341, 342, the equipotential lines 343 run nearly vertically into the first mesa regions 305. In particularly the centrally arranged second doping region 342, which forms a pn-junction with the weakly n-doped semiconductor body 310, ensures that the equipotential lines 343 are pushed into the deep volume of the semiconductor body 310 so that the equipotential lines 343 emerges vertically. The electrical potential is clamped by the respective semiconductor elements in blocking mode. The geometric course of the equipotential line 343 is thus defined by the electrical potential of the semiconductor elements and the doping of the first and second doping regions 341, 342.

In view of the above, a semiconductor substrate 200, 300 is formed which has a first side 201, 301. A source metallization 271 is formed on the first side 201, 301 of the semiconductor substrate 200, 300 and in contact with source regions 211 which are formed in the semiconductor substrate 200, 300. A drain metallization 272 is formed on the first side 201, 301 of the semiconductor substrate 200, 300 and in contact with drain regions 216 which are formed in the semiconductor substrate 200, 300. At least a first doping region 341 is formed in the semiconductor substrate 300, wherein the first doping region 341 has a laterally varying doping dosage and/or a laterally varying implantation depth.

The first doping region 341 can be arranged in the semiconductor substrate 300 at least partially below the drain regions 216 and the source regions 211.

Furthermore, a first group 335 of semiconductor elements 330e, 330d, 330c and a second group 336 of semiconductor elements 330b, 330a, 331 are at least partially formed in the semiconductor substrate 300. The first group 335 of semiconductor elements 330e, 330d, 330c and the second group 336 of semiconductor elements 330b, 330a, 331 form a plurality of semiconductor elements. A second doping region 342 of a second conductivity type can be formed in the semiconductor substrate 300 and extends at least partially below the second group 336 of semiconductor elements 330b, 330a, 331, The second doping region 342 can have a laterally varying doping concentration and/or implantation depth. The first doping region 341 is of a first conductivity type and extends at least partially below the first group 335 of semiconductor elements 330e, 330d, 330c.

The semiconductor device can include a plurality of first trenches 306 extending from the first side 301 into the semiconductor substrate 300, wherein a respective first trench 306 is arranged between respective adjacent semiconductor elements elements 330a, 330b, 330c, 330d, 330e, 331. The first doping region 341 and the second doping region 342 can extend at least partially below the first trenches 306.

The first group 335 of semiconductor elements 330e, 330d, 330c can laterally surround the second group 336 of semiconductor elements 330b, 330a, 331.

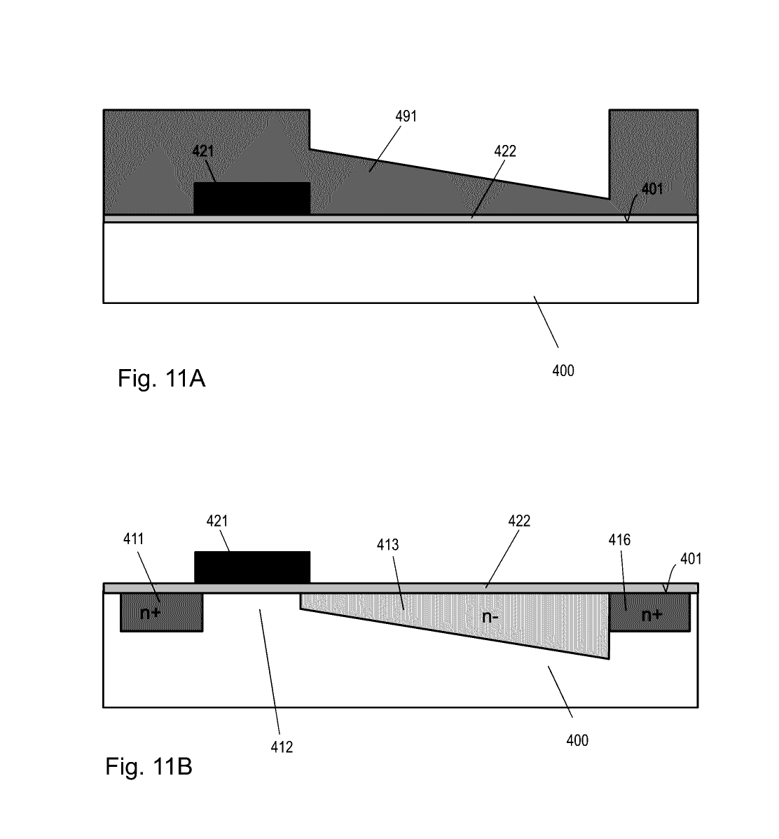

With reference to FIGS. 11A and 11B, a further embodiment is described. A gate dielectric 422 is arranged on a first side 401 of semiconductor substrate 400 to insulate a gate electrode 421 from the semiconductor substrate 400. As illustrated in FIG. 11A, an implantation mask 491 is formed on the gate dielectric 422 and the gate electrode 421 and thus on the first side 401 of the semiconductor substrate 400. It is also possible to form the gate electrode 421 at a later process.

An implantation mask 491 is formed which has a varying thickness at least above a given region of the semiconductor substrate 400 where subsequently a drift region is formed. In the present embodiment, the thickness of the implantation mask 491 reduces from the gate electrode toward a later formed drain region.

Dopants are subsequently implanted into the semiconductor substrate 400 through the implantation mask 491 to form a drift region 413, which has a laterally varying doping dosage and/or a laterally varying depth, between a source region 411 and a drain region 416 which are formed in later processes.

The source region 411 and the drain region 416 are subsequently formed in the semiconductor substrate 400 at the first side 401 of the semiconductor substrate 400. The source and drain regions 411, 416 are laterally spaced from each other with the drift region 413 arranged between the source region 411 and the drain region 416.

A body region 412 is defined between the source region 411 and the drift region 413. The drift region 413 is formed to have an increasing dopant dosage from the body region 412 to the drain region 416. The body region 412 is of opposite conductivity type to the drain region 416, source region 411 and drift region 413.

The source region 411 and the drift region 413 can also be formed prior to the formation of the drift region 413.

In further processes a source metallization is formed to be in contact with the source region 411 and a drain metallization is formed to be in contact with drain regions 416.

The lateral relief of the blocking voltage carried by the drift region is adjusted by the varying doping dosage of the drift region 413. This allows to tailoring the electrical behavior of the semiconductor device.

As described herein, any of the semiconductor devices is a so-called lateral device with source and drain metallization on the same side of the semiconductor substrate. This is beneficial as no edge termination region is needed as for vertical devices.

The semiconductor device is not limited to MOSFETs as described herein, but can includes HEMTs, JFETs, and/or IGBTs.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method for manufacturing a semiconductor device, the method comprising:
providing a semiconductor substrate having a first side;
forming a first implantation mask having a varying thickness on the first side of the semiconductor substrate;
defining regions for respective semiconductor elements in the semiconductor substrate; and
implanting dopants into the semiconductor substrate through the first implantation mask so as to form at least a first doping region arranged at least partially below a first group of semiconductor elements and which has a laterally varying doping dosage and/or a laterally varying implantation depth.

2. The method of claim 1, wherein the first doping region comprises sub-regions of different mean dopant dosage, wherein a first sub-region of the first doping region is formed to be arranged at least partially below a first semiconductor element, and wherein a second sub-region of the first doping region having a mean dopant dosage different than the mean doping dosage of the first sub-region is formed to be arranged at least partially below a second semiconductor element.

3. The method of claim 1, wherein the first doping region laterally extends across the first group of semiconductor elements when seen in a plane projection onto the first side of the semiconductor substrate.

4. The method of claim 1, further comprising:
forming a second implantation mask having a varying thickness on the first side;
implanting dopants into the semiconductor substrate through the second implantation mask so as to form at least a second doping region arranged at least partially below a second group of semiconductor elements and which has a laterally varying doping dosage, wherein the second doping region has a different conductivity type than the first doping region.

5. The method of claim 4, wherein the first doping region laterally surrounds the second doping region.

6. The method of claim 1, wherein forming the first implantation mask comprises:
forming a photosensitive layer on the first side;
exposing the photosensitive layer to radiation through a grayscale mask layer; and
developing the photosensitive layer.

7. The method of claim 1, further comprising:
forming a plurality of first trenches in the semiconductor substrate so as to delimit adjacent first mesa regions.

8. The method of claim 7, further comprising:
forming a plurality of fin regions on each of the first mesa regions, wherein the fin regions extend from an upper side of the first mesa regions to the first side of the semiconductor substrate, and wherein adjacent fin regions are spaced from each other by second trenches which extend to the upper side of the first mesa regions.

9. The method of claim 8, further comprising:
forming a first metallization in electrical contact with a first group of the fin regions; and
forming a second metallization in electrical contact with a second group of the fin regions.

10. The method of claim 8, further comprising:
forming gate electrodes between adjacent ones of the fin regions.

11. A method for manufacturing a semiconductor device, the method comprising:
providing a semiconductor substrate having a first side;
forming a source region in the semiconductor substrate at the first side of the semiconductor substrate;
forming a drain region in the semiconductor substrate at the first side of the semiconductor substrate and laterally spaced from the source region;
forming an implantation mask having a varying thickness on the first side of the semiconductor substrate; and
implanting dopants into the semiconductor substrate through the implantation mask to form a drift region which has a laterally varying doping dosage and/or a laterally varying depth between the source region and the drain region.

12. The method of claim 11, wherein a body region is defined between the source region and the drift region, and wherein the drift region is formed so as to have an increasing dopant dosage from the body region to the drain region.

13. The method of claim 11, wherein the drift region is formed subsequently to forming the source region and the drain region.

14. The method of claim 11, further comprising:
forming a gate dielectric on the first side of the semiconductor substrate and a gate electrode on the gate dielectric so that the gate dielectric is arranged between the semiconductor substrate and the gate electrode.

15. A semiconductor device, comprising:
a semiconductor substrate having a first side;
a source metallization on the first side of the semiconductor substrate and in contact with source regions formed in the semiconductor substrate;
a drain metallization on the first side of the semiconductor substrate and in contact with drain regions are formed in the semiconductor substrate; and
a first doping region formed in the semiconductor substrate and having a laterally varying doping dosage and/or a laterally varying implantation depth.

16. The semiconductor device of claim 15, wherein the first doping region is arranged in the semiconductor substrate at least partially below the drain regions and the source regions.

17. The semiconductor device of claim 15, further comprising:
a first group of semiconductor elements at least partially formed in the semiconductor substrate;
a second group of semiconductor elements at least partially formed in the semiconductor substrate, wherein the first group of semiconductor elements and the second group of semiconductor elements form a plurality of semiconductor elements; and
a second doping region of a second conductivity type formed in the semiconductor substrate and extending at least partially below the second group of semiconductor elements,
wherein the second doping region has a laterally varying doping concentration and/or a laterally implantation depth,
wherein the first doping region is of a first conductivity type and extends at least partially below the first group of semiconductor elements.

18. The semiconductor device of claim 17, further comprising:
a plurality of first trenches extending from the first side into the semiconductor substrate, wherein a respective first trench is arranged between respective adjacent semiconductor elements elements,
wherein the first doping region and the second doping region extend at least partially below the first trenches.

19. The semiconductor device of claim 17, wherein the first group of semiconductor elements laterally surrounds the second group of semiconductor elements.

20. The semiconductor device of claim 15, wherein the first doping region is arranged in the semiconductor substrate between one of the drain regions and one of the source regions.

21. The semiconductor device of claim 15, further comprising:
an enhancement mode semiconductor element at least partially formed in the semiconductor substrate and having a gate, a drain and a source; and
a plurality of depletion mode semiconductor elements at least partially formed in the semiconductor substrate and each having a gate, a drain and a source,
wherein the enhancement mode semiconductor element and the depletion mode semiconductor elements forms a series of semiconductor elements connected in a cascode series.
